(19) United States
(12) Patent Application Publication
(10) Pub. No.: US 2002/0074635 A1
(43) Pub. Date: Jun. 20, 2002

(54) Exposure apparatus, holder container, device manufacturing method, and device manufacturing unit

(75) Inventors: Ken Hattori, Okegawa-shi (JP); Yoshitomo Nagahashi, Takasaki-ku (JP); Kanefume Nakahara, Kumagaya-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Nikon Corporation, Tokyo (JP)

(21) Appl. No.: 09/988,721

(22) Filed: Nov. 20, 2001

Related U.S. Application Data
(63) Continuation of application No. PCT/JP00/03266, filed on May 22, 2000.

(30) Foreign Application Priority Data
May 20, 1999 (JP) 11-139,577

(51) Int. Cl. H01L 23/02

(52) U.S. Cl. 257/678

(57) ABSTRACT

An exposure apparatus comprises a container-mount, on which a holder container that can contain a substrate holder in a sealed manner and that has a door is mounted, the door being able to open and close; an open-close mechanism that opens and closes the door in a manner that the inside of the container mounted on the container-mount is isolated from the outside; and a transport system that exchanges such a holder on a stage with another holder in the container when the open-close mechanism has opened the door. Therefore, the transport system can exchange such holders in a short time in a manner that the inside of the apparatus is isolated from the outside. Accordingly, the down time of the apparatus can be shortened, and the cleanliness of the holders can be maintained all the time. As a result, the productivity of devices such as semiconductor devices can be improved.

### CROSS-REFERENCE TO RELATED APPLICATIONS

This is a continuation of International Application PCT/JP00/03266, with an international filing date of May 22, 2000, the entire content of which being hereby incorporated herein by reference, which was not published in English.

### BACKGROUND OF THE INVENTION

1. Field of the Invention

The present invention relates to an exposure apparatus, a holder container, a device-manufacturing method, and device-manufacturing unit, and more specifically to an exposure apparatus used in a lithography process in the manufacturing of semiconductor devices, liquid crystal display devices or the like, a holder container used when substrate holders for holding a substrate subject to exposure are exchanged, a device-manufacturing method using the exposure apparatus, and a device-manufacturing unit that has a holder, to hold an object, arranged in a space of which cleanliness is higher than that of the outside.

2. Description of The Related Art

In a lithography process for manufacturing semiconductor devices or the like, an exposure apparatus has been mainly used such as a so-called stepper or scanning-stepper, and recently as an exposure light source thereof, a KrF excimer laser is relatively often employed. Furthermore, a lithography system is becoming the mainstream in which such exposure apparatus and a coater-developer (for short, a “C/D” hereinafter, as needed) are connected in-line. That is because, in the lithography process, the sequence of resist coating, exposure and development is performed and it is necessary to, in any of the steps, prevent dust and so forth from entering the apparatus and to perform the sequence as efficiently as possible.

Meanwhile, in semiconductor manufacturing factories a plurality of such exposure apparatuses or lithography systems are arranged in a clean room, and in order to reduce construction cost and running cost of the clean room, cleanliness of the clean room is often set at about class 100 to 1000. Because, also in this case, cleanliness of the insides of the exposure apparatus, the C/D connected in-line with it, and the like can be kept at about class 1, no problem occurs.

In an exposure apparatus for semiconductors, a wafer holder fixed onto a wafer stage attaches to and holds a wafer as a substrate subject to exposure so that the wafer stays flat and does not move.

Here, if foreign substances such as dust are present between the wafer holder holding the wafer and the wafer, the foreign substances degrade the flatness of the exposure surface of the wafer. The degradation of the flatness causes position deviation of a pattern image transferred onto each shot area of the wafer and defective resolution and thus decreases the yields of LSI's. Therefore, in the prior art, at regular intervals the exposure apparatus is stopped, and after the wafer holder is moved to a position that an operator can reach, he/she manually wipes the whole of the face, to contact a wafer, of the wafer holder with a grinder or dust-free cloth, or removes the wafer holder from the wafer stage and cleans it inside the exposure apparatus.

However, when the exposure apparatus is arranged in a clean room having cleanliness of about class 100 to 1000, air outside the exposure apparatus contains more particles than air inside it does, and the cleaning of a wafer holder takes some time. Therefore, upon the cleaning, the less-clean air outside the apparatus gets into the apparatus and thus it is difficult to maintain the cleanliness inside the apparatus.

Meanwhile, the cleaning of the wafer holder is necessary for highly accurate exposure.

Against these backgrounds, a new technology that can maintain the cleanliness of the wafer holder on the wafer stage all the time, that shortens the down time of the apparatus as much as possible, and that improves the productivity of LSI's is needed.

### SUMMARY OF THE INVENTION

This invention was made under such circumstances, and a first purpose of this invention is to provide an exposure apparatus and a device-manufacturing method that can improve the productivity of devices.

A second purpose of this invention is to provide a holder container with which a substrate holder is transported in a sealed manner and that can prevent the damage of the substrate holder during the transport.

A third purpose of this invention is to provide a transport system that can maintain the cleanliness of a space when transporting a holder into and from the clean space in which environment conditions are maintained.

A fourth purpose of this invention is to provide a device-manufacturing unit and adjustment method thereof that can keep environment conditions inside it good regardless of carrying a holder in and out.

According to a first aspect of this invention, there is provided a first exposure apparatus that exposes a substrate held by a substrate holder on a substrate stage, said exposure apparatus comprising: a container-mount on which a holder container is mounted which contains a substrate holder and which has a lid member that can be opened and closed; an open-close mechanism that opens and closes said lid member in a manner that the inside of said holder container mounted on said container-mount is isolated from the outside; and a holder transport system that transports said substrate holder between said holder container and said substrate stage when said open-close mechanism has opened said lid member.

In this embodiment a “substrate holder” may be a dummy holder.

According to this, an open-close mechanism opens and closes the lid member in a manner that the inside of a holder container mounted on the container-mount is isolated from the outside, and a holder transport system transports a substrate holder between the holder container and the substrate stage after the open-close mechanism has opened the lid member. For example, when the holder transport system performs transport of a substrate holder from the substrate stage into the holder container and transport of another substrate holder from the holder container onto the substrate stage, the transport system can exchange the substrate holders in a short time in a manner that the inside of the apparatus is isolated from the outside. Accordingly, the down time of the apparatus can be shortened, and the cleanliness of the substrate holders can be maintained all the time. As a result, the productivity of devices such as semiconductor devices can be improved.

In the first exposure apparatus according to this invention, the holder container may be constructed to contain only one substrate holder, or the holder container may be constructed to contain a plurality of substrate holders at the same time.

In the first exposure apparatus according to this invention, if the holder container can contain a plurality of substrate holders at the same time, said holder transport system may perform transport of one of said substrate holders into said holder container and transport of another of said substrate holders from said holder container in parallel. In this case, because of parallel execution of carrying substrate holders in and out, the substrate holders can be exchanged in a short time.

In the first exposure apparatus according to this invention, if the holder container can contain a plurality of substrate holders at the same time, said holder transport system may perform sequentially transport of one of said substrate holders from said substrate stage into said holder container and transport of another of said substrate holders from said holder container onto said substrate stage. In this case, the structure of the holder transport system can be made simple.

In the first exposure apparatus according to this invention, said holder transport system may serve as at least part of a transport system for said substrate. In this case, because the holder transport system uses at least part of an already existing transport system for substrates, the number of additional components can be limited.

In the first exposure apparatus according to this invention, the holder container is a holder container according to this invention, and said holder transport system may include a transport arm that transports a substrate holder into and from said holder container when said lid member is opened.

In a lithography process, if exposure is performed using the first exposure apparatus according to this invention, a substrate holder on the substrate stage can be kept clean, thereby improving the yields of devices. Furthermore, because the down time of the apparatus is short, highly integrated devices can be manufactured with good productivity. Therefore, according to a second aspect of this invention, there is provided a device-manufacturing method using the first exposure apparatus according to this invention.

According to a third aspect of this invention, there is provided a second exposure apparatus that transfers a pattern onto a substrate by illuminating a mask having said pattern formed thereon with illumination light, said exposure apparatus comprising: a stage that has a set-position from which a detection unit capable of detecting said illumination light is detachable and that is movable holding said substrate; and a transport system that transports said detection unit to said set-position of said stage.

According to a fourth aspect of this invention, there is provided a transport system that transports a holder holding an object in a clean space where environmental conditions are maintained, said transport system comprising: a container that has an inside space where one or more holders can be contained and a lid member that isolates said inside space from the outside; an open-close mechanism that opens and closes said lid member of said container; and a holder transport system that transports a holder between said container and said clean space when said open-close mechanism has opened said lid member.

Here, a “clean space where environmental conditions are maintained” denotes the inside of a first chamber 12 in which a holder is placed, the inside of a second chamber 14 which is connected with it, and a sub-chamber and reserve room which are arranged in the chamber 14, which all will be described in the embodiment. Herein, a “holder” for holding an object may be a dummy holder.

According to this, an open-close mechanism opens and closes a lid member provided for a container in a manner that the inside of the container is isolated from the outside, and when a lid member is opened, a transport system transports a holder between the container and the clean space. In this case, for example, a holder contained in the container in a sealed manner is transported, and then is carried from the container into the clean space in a manner that the inside of the container is isolated from the outside. Therefore, when the inside of the container is already clean, the cleanliness of the holder and the space does not decrease. Meanwhile, when the holder gets dirty in the space, the transport system may transfer the holder into the container as soon as possible and close the lid member using the open-close mechanism. By this, the decrease of the cleanliness of the space can be prevented.

According to a fifth aspect of this invention, there is provided a first exposure system comprising an exposure apparatus that transfers a pattern formed on a mask onto a photo-sensitive substrate, said exposure system wherein a substrate holder to hold said photo-sensitive substrate is transported to a predetermined position of said exposure apparatus by said transport system of this invention.

According to a sixth aspect of this invention, there is provided a second exposure system comprising an exposure apparatus that transfers a pattern formed on a mask onto a photo-sensitive substrate, said exposure system wherein a holder in which a reference illuminance meter is embedded is transported to a predetermined position of said exposure apparatus by said transport system of this invention.

According to a seventh aspect of this invention, there is provided a holder container that contains a substrate holder that can hold a substrate, said holder container comprising: at least one supporting member that supports at least one substrate holder; and a lid member that isolates the inside space, where said at least one supporting member is provided, from the outside; wherein said at least one substrate holder is contained in said inside space isolated from the outside by said lid member.

According to an eighth aspect of this invention, there is provided a device-manufacturing unit that has a holder, to hold an object, arranged in a space of which cleanliness is higher than that of the outside, said device-manufacturing unit comprising: an open-close mechanism that communicates the inside of a container containing said holder in a sealed manner to said space while isolating the inside of said container from said outside; and a transport system that transports said holder between said container and said space.

Here, a “space of which the cleanliness is higher than that of the outside” means the same as a “clean space where environmental conditions are maintained” does.

According to this, an open-close mechanism connects the inside of a container containing a holder in a sealed manner and the cleaner space while isolating the inside of the container from the outside, and a transport system transports a holder between the container and the space. For example, when the transport system transports a clean holder from the container into the space, the decrease of the cleanliness of the space by the holder does not occur. Meanwhile, if the transport system transports the holder that has got dirty from the space into the container, after that, the holder needs to be contained in the container in a sealed manner. By this, the decrease of the cleanliness of the space can be prevented. The cleanliness of the space can be kept high regardless of carrying a holder in and out.

In this case, it is preferable that the concentration of impurities inside said container is set at a level not higher than that of said space.

In a device-manufacturing unit according to this invention, the atmosphere inside said container may be set to be substantially the same as that of said space. In this case, said container may be filled with gas having substantially the same characteristics as that of said space. In either case, the cleanliness of the space can be kept high.

In a device-manufacturing unit according to this invention, said holder may hold a sensitive object and an exposure main body that exposes said sensitive object to an energy beam may be arranged in said space. That is, the device-manufacturing unit according to this invention may be an exposure apparatus that exposes a sensitive object to an energy beam. In this case, chemically clean gas having high transmittance to said energy beam may be supplied to said space. In this case, the optical characteristics (transmittance, illuminance uniformity, aberration, etc.) of the illumination optical system and projection optical system can be kept good.

According to a ninth aspect of this invention, there is provided an adjustment method with which to adjust a device-manufacturing unit that has a holder, to hold an object, arranged in a space thereof having a higher cleanliness than that of the outside of said device-manufacturing unit, said adjustment method wherein the inside of a container to contain a holder in a sealed manner is communicated to said space in a manner that the inside of said container is isolated from said outside, and wherein a holder is transported from said space into said container and a clean holder is transported into said space.

According to this, the inside of a container to contain a holder in a sealed manner is communicated to the cleaner space in a manner that the inside of the container is isolated from the outside, and a holder is transported from the space into the container and a clean holder is transported into the space. Therefore, because when the cleanliness of a holder in the space has decreased, the holder is replaced with a clean holder, the decrease of the cleanliness of the space can be prevented.

According to a tenth aspect of this invention, there is provided a detection unit that can be used in an exposure apparatus that transfers a pattern formed on a mask onto a substrate by illuminating said mask with illumination light, said detection unit comprising: a detecting portion that can detect illumination light; and a power supply portion that supplies power to said detecting portion for driving it, and which is transported by a transport system of said exposure apparatus in order to be set up in a predetermined position inside said exposure apparatus.

### BRIEF DESCRIPTION OF THE DRAWINGS

FIG. 1 is a schematic plan view showing a lithography system according to an embodiment of this invention;

FIG. 2 is a schematic oblique view of an exposure apparatus, as seen in the direction of arrow A in FIG. 1;

FIG. 3 shows a partial section through a second chamber in FIG. 1, as seen from the right side;

FIG. 4 is a schematic sectional view, taken in the horizontal direction, of the exposure apparatus in FIG. 1, showing mainly the wafer loader system;

FIG. 5 is a side view of a container-mount and things around it in FIG. 4;

FIG. 6 is a cross-sectional view of another embodiment of a holder container containing a wafer holder;

FIG. 7 is a view for explaining the method of attaching the cover of the holder container in FIG. 6 to the container main body;

FIG. 8 is a view showing the holder container in FIG. 6 mounted on the container-mount;

FIG. 9 is a view showing a state where the cover is separated from the container main body of the holder container mounted on the container-mount in FIG. 8;

FIG. 10 is a flow chart for explaining a device-manufacturing method according to this invention; and

FIG. 11 is a flow chart showing the process of step 304 of FIG. 10;

### DETAILED DESCRIPTION OF THE PREFERRED EMBODIMENTS

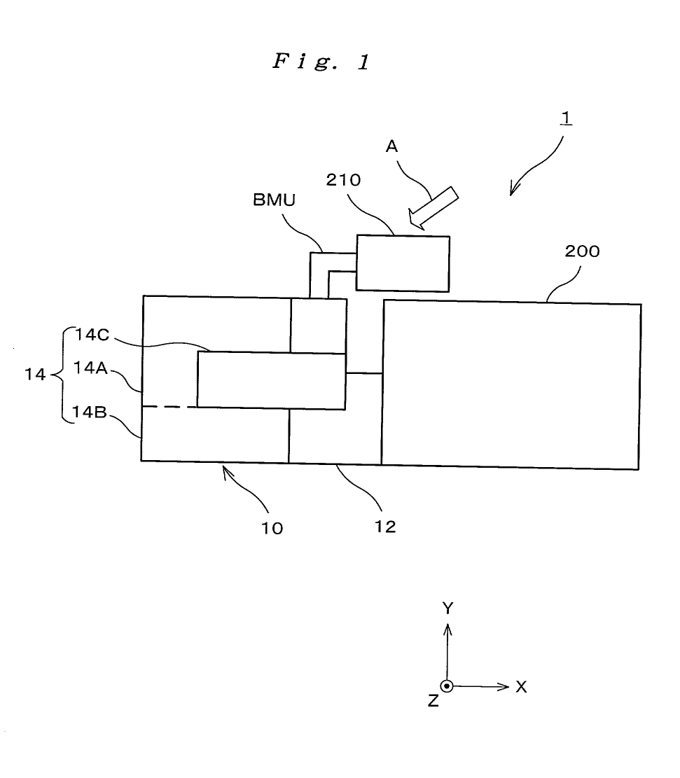

An embodiment of the present invention will be described below on the basis of FIGS. 1 to 5.

FIG. 1 shows the schematic plan view of a lithography system of the embodiment according to this invention. The lithography system 1 comprises an exposure apparatus 10 and a coater-developer (hereinafter, a “C/D” for short) that is connected in-line with the exposure apparatus 10 and that serves as a substrate-processing unit. This lithography system is arranged in a clean room having a cleanliness of about class 100 to 1000. Hereinafter, the longitudinal direction (Y-axis direction) in the drawing of FIG. 1 is referred to as the fore-and-aft direction of the lithography system 1, where the +Y direction is the direction toward the back, and where the −Y direction is the direction toward the front. Furthermore, the lateral direction (X-axis direction) in the drawing of FIG. 1 is referred to as the lateral direction (toward the side) of the lithography system 1.

The exposure apparatus 10 comprises a first chamber 12 that is disposed on the left side of and adjacent to the C/D 200 and that is connected in-line with the C/D 200 and a second chamber 14 that is disposed on the left side of and adjacent to the first chamber 12. It is remarked that in the insides of the first chamber 12, the second chamber 14, the C/D 200 and the like, the preferable environment conditions and a cleanliness of about class 1 are maintained.

The second chamber 14 comprises a first portion 14A housing an exposure-apparatus main body described later, a second portion 14B housing a reticle transport system described later, and a third portion 14C that is disposed above the first and second chambers 12, 14 and that houses an illumination optical system. And the illumination optical system of the third portion 14C is connected through a beam-matching-unit BMU to a laser light source (ArF excimer laser, KrF excimer laser, F₂ laser or so forth) 210 as an exposure light source.

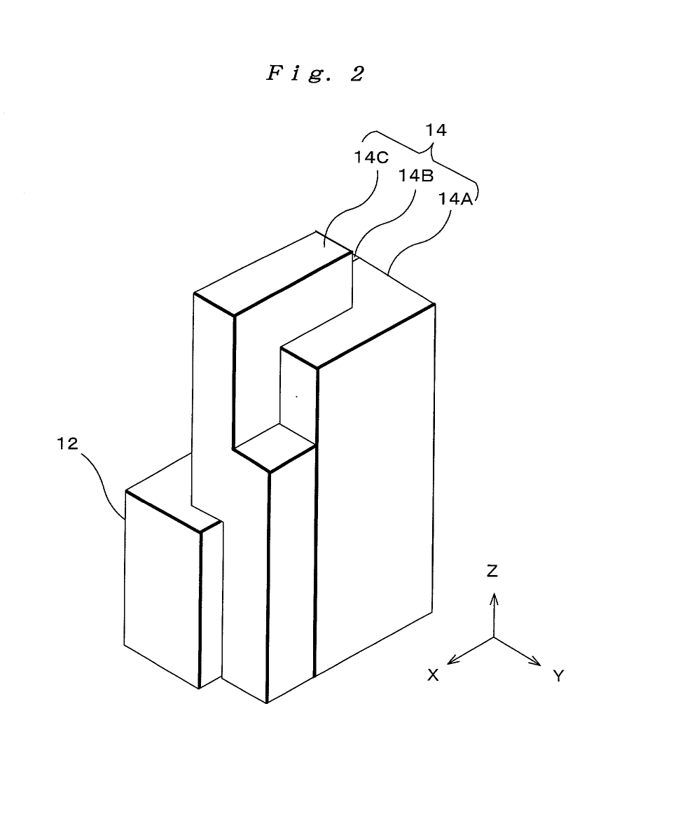

FIG. 2 shows a schematic, oblique view of the exposure apparatus 10 as seen in the direction of an arrow ‘A’ in FIG. 1, with omitting the BMU and the excimer laser light source 210. As seen in FIG. 2, the second chamber 14 comprises the first portion 14A of which the YZ-section is shaped like an ‘L’ letter, the second portion 14B that is located on the front lower portion of the first portion 14A and that forms a rectangular solid together with the first portion 14A, and the third portion 14C that extends upward behind the first chamber 12 and on a side of the first portion 14A, having a bend forward over the first chamber 12 and that has a protrusion extending over the first portion 14A.

The first chamber 12 houses a substrate transport system and most part of a wafer loader system as a holder transport system as described later.

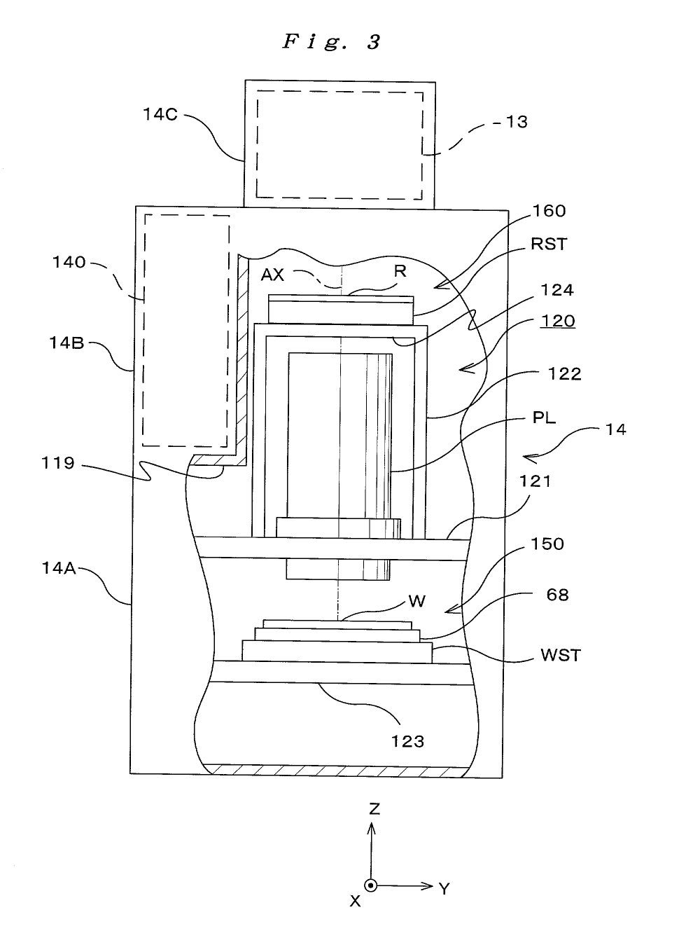

FIG. 3 shows a partial section through the second chamber 14 as seen from the right side in FIG. 1. As seen in FIG. 3, the first portion 14A and the second portion 14B of the second chamber 14 are divided by a division member 119. Note that most of the upright part of the division member 119 is open (not shown) and through it the second portion 14B is in communication with the first portion 14A housing the exposure-apparatus main body 120, which transfers a pattern of a reticle R as a mask onto a wafer W as a substrate using a step-and-scan method.

The exposure-apparatus main body 120 is provided with a main column comprising a main-frame 121 holding a projection optical system PL, a support-frame 122 provided on the upper face of the main-frame 121, and a wafer stage base 123 suspended from the main-frame 121.

The top of the support-frame 122 serves as a reticle base 124, and on the reticle base 124 a reticle stage RST for holding a reticle R is arranged. The reticle stage RST can be finely driven in two dimensions along an X-Y plane perpendicular to the optical axis (coincide with the optical axis AX of the projection optical system PL) of an illumination optical system 13 housed in the third portion 14C so as to position the reticle R, by a reticle-stage-drive portion (not shown) constituted by, e.g., a magnetic-levitation-type and two-dimensional linear actuator, and can also be driven in a predetermined scan direction (herein, the X-axis direction) at a specified scan speed. The position of the reticle stage RST is detected all the time with a resolving power of, e.g., about 0.5 to 1 nm by a reticle laser interferometer (not shown), and the position information is sent to a stage controller and then a main controller (none are shown).

The projection optical system PL is, for example, an optical reduction system of which the optical axis AX is parallel to a Z-axis direction, which is telecentric on both sides, and which has a predetermined projection ratio of, e.g., 1/5 or 1/4. Therefore, when the illumination area of the reticle R is illuminated with the exposure light from the illumination optical system 13, the reduced image (partially inverted image) of the illuminated part of a circuit pattern on the reticle R is transferred onto an exposure area on the wafer W coated with resist (photosensitive material) through the projection optical system PL by the illumination light having passed through the reticle R.

A wafer stage WST is disposed on the wafer stage base 123, and a wafer holder 68 as a substrate holder is fixed on the wafer stage WST by vacuum chucking. On the wafer holder 68, the wafer W having a diameter of 12 inch is fixed via vacuum chuck, electrostatic chuck or the like (not shown) so as to prevent the displacement of the wafer W during the movement of the wafer stage WST.

The wafer stage WST is driven in two dimensions, X-axis and Y-axis, via a wafer-stage-drive portion (not shown) constituted by, e.g., a magnetic-levitation-type and two-dimensional linear actuator. That is, the wafer stage WST can be moved in a non-scan direction (the Y-axis direction) perpendicular to the scan direction as well as being moved in the scan direction (the X-axis direction) at a specified scan speed so as to position a plurality of shot areas on the wafer in the exposure area, conjugate to the illumination area on the reticle, and the step-and-scan sequence is performed where the scan-exposure operation of a shot area on the wafer and the moving of a next shot to a scan start position for exposure are repeated.

The position of the wafer stage WST is detected all the time with a resolving power of, e.g., about 0.5 to 1 nm by a wafer laser interferometer (not shown), and the position information is sent to a stage controller and then the main controller (none are shown).

In addition, provided in the exposure-apparatus main body 120 are detection systems such as an alignment microscope of an off-axis method that detects an alignment mark (wafer mark) of each shot area (divided area) on the wafer W and a focus sensor for detecting the position, in the optical-axis direction, of the wafer W (none are shown), and the measurement results of these detection systems are sent to the main controller.

A reticle loader system 140 for delivering a reticle to the reticle stage RST is housed in the second portion 14B. In this embodiment, as seen in FIG. 3, above a wafer stage system 150 composed of the wafer stage WST and a drive portion thereof, the reticle loader system 140 and a reticle stage system 160 composed of the reticle stage RST and a drive portion thereof are arranged in the fore-and-aft direction. Furthermore, disposed on the right side of the wafer stage system 150 in FIG. 1 is the first chamber 12 housing the wafer loader system.

An illumination system housing that houses optical members composing the illumination optical system 13 has the same shape as the third portion 14C of the second chamber 14 shown in the oblique view of FIG. 2. That is, inside the third portion 14C, the illumination system housing extends upward behind the first chamber 12, having a bend forward over the first chamber 12 at a predetermined height and has a protrusion extending over the first portion 14A. In this case, the upper end face of the third portion 14C of the second chamber 14, which portion houses the illumination optical system 13, almost coincides with the left side face of the first portion 14A; the width, in the lateral direction, of the third portion 14C on the right side of the first portion 14A is such that there is some distance between the right side faces of the first chamber 12 and the third portion 14C.

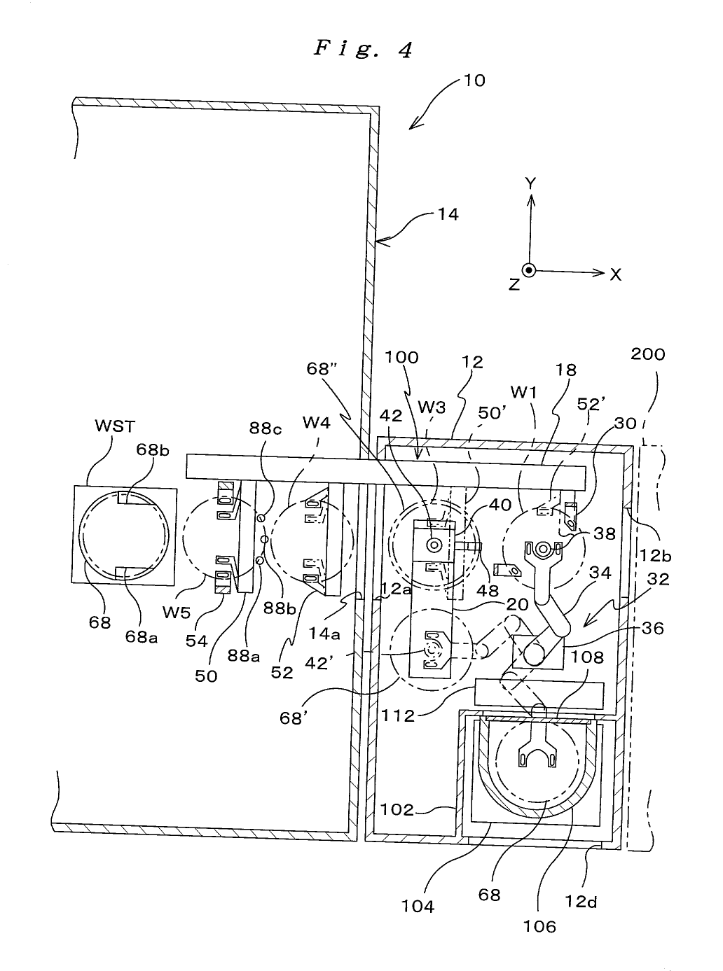

FIG. 4 shows a schematic view of a lateral section through the exposure apparatus 10 as seen from the top, mainly illustrating the substrate transport system and a wafer loader system 100 as the holder transport system. It is noted that, in FIG. 4, an air-conditioning system and the like are omitted and that only the wafer stage WST of the exposure-apparatus main body is shown.

The wafer loader system is disposed near the back in the first chamber 12 and comprises, as transport guides, an X-guide 18 extending in the lateral direction (X-axis direction) and a Y-guide 20 that is arranged in front of the X-guide 18 and that extends in the fore-and-aft direction (Y-axis direction) over a predetermined length.

The X-guide 18 extends in the X-axis direction from a position near the right side wall of the first chamber 12 through an opening 12a of the first chamber 12 and an opening 14a of the second chamber 14 to the inside of the second chamber 14.

In addition, close to the C/D 200 and near the front inside the first chamber 12, a container-mount 104 is disposed on which a holder container 106 as a container is mounted.

Made in the front wall (−Y side) of the first chamber 12 is an opening 12d that is opposite the container-mount 104 in a plan view and through which a holder container 106 is transferred. The opening 12d is from a height of about 900 mm to a height of about 1200 mm above the floor in size.

As the holder container 106, a container is used that has the same structure as a Front Opening Unified Pod (hereinafter, FOUP for short), a kind of substrate container. It is remarked that the FOUP contains a plurality of wafers such that they are spaced vertically a predetermined distance apart from each other, has an opening made in only one side thereof, and is a open-close-type container (wafer cassette) having a door (lid) 25 for opening and closing the opening. Such a container is disclosed in, for example, Japanese Patent Laid-Open No. 8-279546.

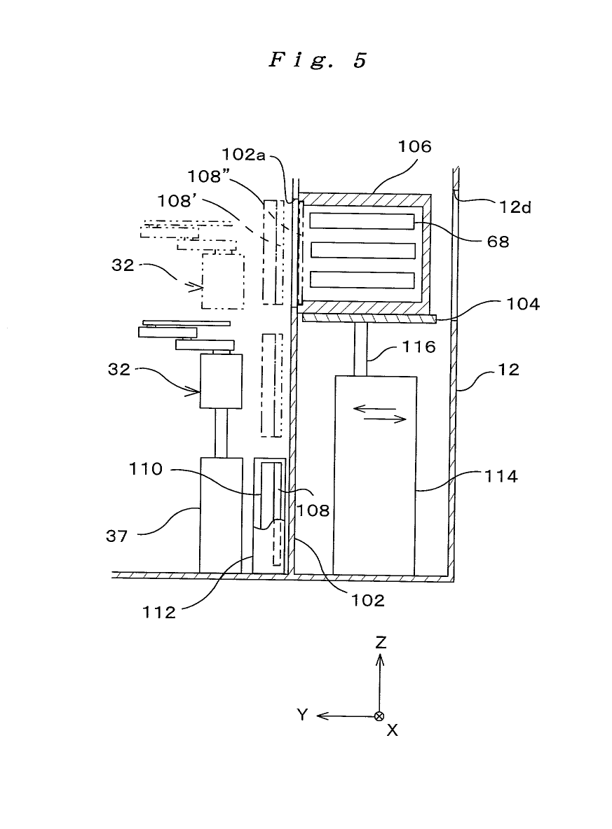

FIG. 5 shows a side view of the container-mount 104 and things around it. As seen in FIG. 5, a rack composed of a plurality of shelves (herein, two shelves; not shown) is provided in the holder container 106 so as to store three wafer holders 68, as substrate holders, vertically spaced a predetermined distance apart. Furthermore, the holder container 106 has an opening made in only one side thereof (the +Y side) and has a door 108 as a lid member for opening and closing the opening. When a wafer holder 68 is taken out of the holder container 106, the holder container 106 is pushed against a division wall 102 around an opening 102a to open the door 108 through the opening 102a. For that purpose, in this embodiment an open-close mechanism (opener) 112 for the door 108 is provided on the +Y side face of the division wall 102.

As shown in FIG. 5, the opening 102a is substantially the same as the opening 12d in height and size, that is, from a height of about 900 mm to a height of about 1200 mm above the floor in size.

Moreover, as shown in FIG. 5, the container-mount 104 is fixed on the upper face of a drive axis 116 that is driven in the Y-direction by a slide mechanism 114 fixed on the bottom of the first chamber 12, which mechanism is controlled by a controller (not shown).

Furthermore, contained in the open-close mechanism 112 is an open-close member 110 provided with a mechanism for fixing to the door 108 by vacuum or mechanical connection and unfastening a key (not shown) of the door 108. In a usual state (the state of the FOUP not being in place) the open-close member 110 is fitted and fixed to the opening 102a so that the inside surrounded by the division wall 102, etc., is not left open. The open-close mechanism 112 is also controlled by a controller (not shown).

In the below, the operation of opening the door of the holder container 106 will be briefly described.

After a holder container 106 has been transferred through the opening 12d of the first chamber 12 onto the container-mount 104 by PGV (Personnel Guided Vehicle) or AGV (Automatic Guided Vehicle), the controller (not shown) drives the container-mount 104 in the +Y direction via the slide mechanism 114 and pushes the holder container 106 against the division wall 102 (refer to FIG. 5). Next, the controller moves the door 108 of the holder container 106 from the position indicated by an imaginary line 108″ in FIG. 5, i.e. a position when the container 106 is pushed against the division wall 102, by way of the position indicated by an imaginary line 108′ to the position indicated by a solid line inside the open-close mechanism 112 along with the open-close mechanism 112 and open-close member 110 so as to open the door 108. Before the operation of opening the door 108, the controller has checked for each shelf whether or not a wafer holder is on the shelf of the container, using holder-detection sensors (not shown) and has stored the results in a memory (not shown).

Because the same method as the method of opening and closing the door 108 by the open-close mechanism 112 is disclosed in detail in Japanese Patent Laid-Open No. 8-279546 and the like, further description is omitted.

Referring back to FIG. 4, the Y-guide 20 extends in the Y-axis direction from near the X-guide 18 almost to the center of the first chamber 12. On the upper face of the Y-guide 20 a slider 40 is mounted that is driven along the Y-guide 20 by a linear motor, etc. (not shown), and on the upper face of the slider 40 a Y-axis turntable 42 is fixed. The Y-axis turntable 42 is composed of a substrate holder portion that is fixed on the upper face of the slider 40 and that holds a wafer W as a substrate (indicated by a symbol W3 in FIG. 4) and a drive unit for rotating it. Furthermore, a wafer edge sensor 48 composed of a light-emitting device and a light-receiving device (e.g. a photo diode and a CCD line sensor) is fixed integrally to the slider 40 via a support member. The wafer edge sensor 48 is used for rough positioning of a wafer W.

Above the right end of the X-guide 18 (furthest right position of an unload-X-axis arm 52 indicated by a numeral 52′), an in-line-interface load arm (for short, a “in-line-I/F load arm”) 30 is arranged which delivers and receives a wafer W to and from a transport arm (load arm) of the C/D 200 side, the unload-X-axis arm 52 being described later. Furthermore, below the in-line-I/F load arm 30 an in-line-interface unload table (for short, a “in-line-I/F unload table”) 38 is arranged.

On the right side of the Y-guide 20 (the +X side in FIG. 4) and opposite to the holder-container-mount 104, a horizontal, articulated robot (scalar robot) 32 is disposed. This horizontal, articulated robot 32 (hereinafter, the robot 32 for short, as needed) comprises an arm 34 that can stretch and fold, and rotate in the X-Y plane and a drive portion 36 for driving this arm 34, and is driven vertically (in the Z-direction) within a predetermined range by an up-down-movement mechanism 37 (not shown in FIG. 4; refer to FIG. 5) disposed on the bottom of the first chamber 12. Therefore, in this embodiment the arm 34 of the robot 32 can move up and down as well as stretch and fold, and rotate in the X-Y plane. The robot 32 is used for the transport of a wafer holder as well as for the transport of a wafer. The sequence of transporting a wafer or wafer holder will be described later.

On the X-guide 18, a load-X-axis arm 50 and an unload-X-axis arm 52 are arranged that are driven by an up-down-movement slide mechanism (not shown) having the mover of a linear motor so as to move along the X-guide 18.

The load-X-axis arm 50 is driven by the up-down-movement slide mechanism (not shown), can be moved from near the position indicated by an imaginary line 50′ in FIG. 4 to a predetermined loading position (wafer delivery position) indicated by a solid line 50 and can also be moved vertically within a predetermined range. Disposed near the loading position is a stage-delivery arm 54 described later. Furthermore, the unload-X-axis arm 52 is driven by the up-down-movement slide mechanism (not shown), can be moved from the position indicated by an imaginary line 52′ in FIG. 4 to the position of the stage-delivery arm 54 along a movement plane below the movement plane of the load-X-axis arm 50 and can also be moved vertically within a predetermined range.

The stage-delivery arm 54 forms a part of a pre-alignment unit (not shown). The pre-alignment unit comprises an up-down-movement rotation mechanism (not shown) for supporting the stage-delivery arm 54 and moving vertically and rotating it, three CCD cameras 88a, 88b, 88c arranged above the stage-delivery arm 54. The CCD cameras 88a, 88b, 88c are for individually detecting the outer edge of a wafer held by the stage-delivery arm 54, and are arranged so as to be able to pick up the outer edge of a 12-inch wafer (denoted by wafer W5 in FIG. 4). Out of these, the center CCD camera 88b detects the V-shaped notch of the wafer.

The pre-alignment unit detects the edge of the wafer, using the CCD cameras 88a, 88b, 88c and, based on the detection results, obtains the X, Y, θ errors of the wafer and rotates the stage-delivery arm 54 via the up-down-movement rotation mechanism so as to correct the θ error.

Made in the upper portion of both sides of the wafer holder 68 on the wafer stage WST are notches 68a, 68b which extend in the X-direction so that the tips of the claws of the stage-delivery arm 54 and the unload-X-axis arm 52 can be inserted and which have a predetermined depth.

In the right side wall (the +X side) of the first chamber 12, as shown in FIG. 4, an opening 12b is made through which a wafer is delivered to and removed from the first chamber 12, which is connected in-line with the C/D 200 through the opening 12b.

Although omitted in the above description, a means, for preventing the displacement of the wafer W during operation, such as vacuum chuck or electrostatic chuck is provided on the arms and the tables, which hold and carry the wafer W or a wafer holder 68.

Next, the operation of the lithography system 1 of this embodiment, which system has the above structure will be described on the basis of FIG. 4 mainly focusing on the transport sequence of a wafer W or a wafer holder 68.

It is noted that in the below description, to make it simpler, the description of the on-off operation of vacuum chuck upon delivery of the wafer W or wafer holder will be omitted. First the transport of the wafer will be described.

A C/D-side load arm (not shown) holding the wafer W coated with resist is inserted through the opening 12b into the first chamber 12, and the wafer is transferred from the C/D-side load arm to the in-line-I/F load arm 30. The C/D-side load arm has such a shape as does not interfere with the in-line-I/F load arm 30 upon delivery of the wafer W, and the delivery of the wafer W is performed by, e.g., lowering the C/D-side load arm (or lifting the in-line-I/F load arm 30). In FIG. 4 the wafer W after the completion of the delivery is indicated by a symbol W1.

After the completion of the delivery, the C/D-side load arm (not shown) moves back out of the first chamber 12 through the opening 12b. After confirming via a sensor (not shown) that the C/D-side load arm has moved out, the controller (not shown) inserts the arm 34 under the wafer W held by the in-line-I/F load arm 30 via the drive unit 36 of the robot 32. Then by, e.g., lifting the robot 32 via the up-down-movement mechanism 37 or lowering the in-line-I/F load arm 30, the wafer is transferred from the in-line-I/F load arm 30 to the arm 34 of the robot 32.

Next, the controller rotates, and stretchs and folds the arm 34 of the robot 32 holding the wafer W to transport the wafer W to the position indicated by an imaginary line W3. At this time, the controller controls the robot 32 to take such a route that the wafer W and the arm 34 of the robot 32 do not interfere with the in-line-I/F load arm 30, the first chamber 12, the support member of the wafer edge sensor 48, etc. Meanwhile, the Y-axis turntable 42 moves to the position indicated by a solid line in FIG. 4.

Then the controller has the arm 34 of the robot 32 pass the wafer W to the Y-axis turntable 42 by lowering the robot 32 (or lifting the Y-axis turntable 42).

Next, the controller rotates the Y-axis turntable 42 to turn the wafer W on the Y-axis turntable 42, and based on light-amount signals from the wafer edge sensor 48, obtains the direction of the notch of the wafer W relative to the wafer center and the deviation, in X-Y two dimensions, of the wafer center relative to the Y-axis turntable 42. Because a specific method for obtaining the notch's direction and the deviation of the wafer center is disclosed in detail in, e.g., Japanese Patent Laid-Open No. 10-12709, further description is omitted. Likewise, with a wafer having an orientation-flat formed thereon, the rotation and the center deviation of the wafer can be obtained using the wafer edge sensor 48.

The controller controls the rotation angle of the Y-axis turntable 42 such that the notch's direction obtained coincides with a predetermined direction, e.g. the +X direction, and also drives finely the Y-axis turntable 42 in the Y-direction according to the Y-direction component of the deviation of the wafer center. In this way the controller corrects the rotation and the position deviation, in the Y-direction, of the wafer W.

At the completion of correcting the rotation and the position deviation in the Y-direction of the wafer W, the load-X-axis arm 50 has moved to near the position indicated by the imaginary line 50′ in FIG. 4, and the controller controls the stop position of the load-X-axis arm 50 such that the center of the wafer W coincides with the center of the claws of the load-X-axis arm 50, thereby correcting the X-direction component of the center deviation.

In this way, the controller performs rough positioning (pre-alignment of a first step) of the wafer W.

After the rough positioning of the wafer W, the controller has the Y-axis turntable 42 pass the wafer W to the load-X-axis arm 50 by, e.g., lifting the load-X-axis arm 50 (or lowering the Y-axis turntable 42).

After the completion of delivering the wafer W to the load-X-axis arm 50, the controller moves the load-X-axis arm 50 from the position of the imaginary line 50′ to the loading position indicated by a solid line. In this way the wafer W is transported to the position indicated by the imaginary line W5.

It is noted that when the previous wafer is left in the loading position indicated by the imaginary line W5, the controller makes the wafer W, i.e. the load-X-axis arm 50, stand by in the position indicated by an imaginary line W4.

After the load-X-axis arm 50 moves to the loading position, the controller has the load-X-axis arm 50 pass the wafer W to the stage-delivery arm 54 by lifting the stage-delivery arm 54 (or lowering the load-X-axis arm 50). After the completion of the passing, the controller starts to move the load-X-axis arm 50 toward the position indicated by the imaginary line 50′ for preparing for the transport of a next wafer. At this time the controller moves the load-X-axis arm 50 as close to the position indicated by the imaginary line 50′ as possible such that the load-X-axis arm 50 does not interfere with a wafer W in the position indicated by the imaginary line W3.

After confirming that the load-X-axis arm 50 has retreated, the controller drives the stage-delivery arm 54 holding the wafer W upward by a predetermined amount via the up-down-movement rotation mechanism constituting the pre-alignment unit (not shown). Then the controller instructs the pre-alignment unit to detect the edge (outer shape) of the wafer W using the CCD cameras 88a, 88b, 88c, obtains the X, Y, θ errors of the wafer based on the detection results and rotates the stage-delivery arm 54 via the up-down-movement rotation mechanism so as to correct the θ error. Because the X, Y, θ errors of the wafer W are detected in order to correct residual errors after the rough positioning of the first step and errors generated during the transport and delivery, the errors of the wafer (pre-alignment of a second step) are more accurately detected.

It is noted that the X, Y errors obtained based on the measurement of the wafer's outer shape by the pre-alignment unit are sent to the main controller (not shown) and that the main controller corrects the errors by, for example, adding offsets equal to the errors upon search-alignment of the wafer performed later. Needless to say, the position of the wafer stage WST staying in the loading position may be adjusted to correct the X, Y errors.

During the pre-alignment of the second step, exposure processing (alignment, exposure) of another wafer on the wafer stage WST are being performed. Furthermore, during this exposure, the unload-X-axis arm 52 stands by in the loading position and under the stage-delivery arm 54.

And after the completion of transferring the pattern of the reticle R onto all shot areas of the wafer, according to an instruction from the main controller (not shown), the stage controller (not shown) moves the wafer stage WST from the exposure-finish position shown in FIG. 4 toward the loading position to transport the wafer W already exposed to the unloading position (i.e. loading position).

When the wafer stage WST is moved toward the loading position, the claws on the tips of the unload-X-axis arm 52, which claws are provided with chucking, fit into the notches 68a, 68b of the wafer holder 68.

After the movement of the wafer stage WST has been completed, according to an instruction from the main controller, the controller drives the unload-X-axis arm 52 upward by a predetermined amount so as to pass the already-exposed wafer W from the wafer holder 68 on the wafer stage WST to the unload-X-axis arm 52, i.e. to unload the wafer from the wafer holder 68.

Next, the controller drives the unload-X-axis arm 52 to the position indicated by the imaginary line 52′ in FIG. 4. By this, the unload-X-axis arm 52 transports the wafer from the loading position indicated by the imaginary line W5 to under the position indicated by the imaginary line W1. At this time, the controller makes the Y-axis turntable 42 and the slider 40 as one piece retreat to the position indicated by an imaginary line 42′. It is noted that while performing the pre-alignment of the first step on a next wafer, the controller makes the unload-X-axis arm 52 stand by near the position indicated by the solid line until the completion of the pre-alignment.

After the unload-X-axis arm 52 has retreated from the loading position, the controller instructs the pre-alignment unit to lower the stage-delivery arm 54 via the up-down-movement rotation mechanism so that a wafer W subject to exposure is loaded onto the wafer holder 68. When the stage-delivery arm 54 is lowered, the claws on the tips of the stage-delivery arm 54, which claws are provided with chucking, fit into the notches 68a, 68b of the wafer holder 68.

After confirming that the stage-delivery arm 54 has been lowered a predetermined amount apart from the back of the wafer W, the main controller instructs the stage controller to move the wafer stage WST to the start position of the exposure sequence. By this, the stage controller moves the wafer stage WST in the −X direction to the start position of the exposure sequence (the position indicated by the solid line in FIG. 4). After that, the exposure sequence (search alignment, fine alignment such as EGA, and exposure) is performed on the wafer on the wafer holder 68. Because this exposure sequence is the same as that of the usual scanning stepper except for the measuring of the position deviation of the wafer on the wafer stage by the photo-sensors, detailed explanation thereof is omitted.

When the wafer stage WST is moved to the start position of the exposure sequence, the wafer stage WST is smoothly moved without the wafer holder 68 contacting the claws of the stage-delivery arm 54 because the notches 68a, 68b are made in the wafer holder 68.

In this way, because this embodiment efficiently uses the high-speed movement of the wafer stage WST when replacing a wafer on the wafer holder 68, the time for replacing the wafer can be shortened, thereby improving throughput.

After the controller receives from the main controller a signal indicating that the wafer stage WST has retreated from the loading position, the controller lifts the stage-delivery arm 54 to a height in the loading position and where the arm 54 receives a wafer from the load-X-axis arm 50 so as to prepare for the transport of a next wafer.

Meanwhile, by, e.g., lowering the unload-X-axis arm 52 (or lifting the in-line-I/F unload table 38), the controller has the unload-X-axis arm 52 pass the wafer W to the in-line-I/F unload table 38 after the wafer W having been transported to under the position indicated by the imaginary line W1.

After the completion of the passing, the controller moves the unload-X-axis arm 52 to the loading position and makes it stand by for the unloading of a next wafer.

After the controller confirms that the unload-X-axis arm 52 has moved to near the opening 12a of the first chamber 12, the controller informs the C/D 200 side of that. By this, a C/D-side unload arm (not shown) is inserted through the opening 12a into the first chamber 12, and the wafer W is transferred from the in-line-I/F unload table 38 to the C/D-side unload arm by, for example, lifting the C/D-side unload arm (or lowering the in-line-I/F unload table 38). It is noted that the C/D-side unload arm may also be used as the C/D-side load arm.

After the completion of the transfer, the C/D-side unload arm holding the wafer w retreats through the opening 12a from the first chamber 12.

The exposure apparatus 10 repeats exposure and replacing a wafer on the wafer holder 68 as in the above. However, if droplets of resist coating wafers or particles that are generated when the stage moves and that are floating in the exposure apparatus stick to and accumulate on the wafer holder 68, the flatness of wafers cannot be ensured as described above. So as to prevent such problem from occurring, wafer holders are replaced at predetermined intervals, for example, each time exposure of a predetermined number of wafers in each lot is completed.

Next, the replacement sequence of a wafer holder will be described mainly focusing on the control operation of the controller (not shown).

As a premise it is assumed that the door 108 of the container 106 is opened in the way described above, and that the controller has checked for each shelf in the container whether or not a wafer holder is on the shelf, using holder sensors (not shown) and has stored the check results in a memory (not shown).

After the completion of exposure of a predetermined number of wafers in the lot, according to an instruction from the main controller, the stage controller moves the wafer stage WST from the position shown in FIG. 4 to the unloading position (i.e. the loading position) slowly. During this movement, the stage controller lifts the wafer holder 68 from the wafer stage WST by a predetermined amount via a delivery mechanism (not shown)

When the wafer stage WST has arrived in the unloading position, the unload-Y-axis arm 52 has been already inserted under the wafer holder 68. Next, according to an instruction from the main controller, the controller lifts the unload-Y-axis arm 52 by a predetermined amount to transfer the wafer holder 68 from the wafer stage WST to the unload-Y-axis arm 52.

Next, the controller moves the unload-Y-axis arm 52 to near the position indicated by the imaginary line W3 in FIG. 4. By this, the unload-Y-axis arm 52 transports the wafer holder 68 from the loading position to the position indicated by an imaginary line 68″. At this time, the Y-axis turn table 42 is standing by in the position indicated by a solid line in FIG. 4.

After the wafer holder 68 is transported to the position indicated by the imaginary line 68″, the controller has the wafer holder 68 transferred from unload-Y-axis arm 52 to the Y-axis turntable 42 by, e.g., lifting the Y-axis turntable 42 (or lowering the unload-Y-axis arm 52).

After the transfer, the controller moves the unload-Y-axis arm 52 toward the loading position by a predetermined amount to make it retreat from the position W3.

After confirming that the unload-Y-axis arm 52 has moved to a position where the unload-Y-axis arm 52 does not interfere with the wafer holder on the Y-axis turntable 42, the controller moves the slider 40 and Y-axis turntable 42 as one piece to the position indicated by the imaginary line 42′ in FIG. 1. By this, the wafer holder 68 is transported from the position indicated by the imaginary line 68″ in FIG. 4 to the position indicated by the imaginary line 68′.

Next, the controller has the robot 32 insert the arm 34 under the wafer holder 68 located in the position of the imaginary line 68′ by stretching and folding, rotating, and lowering it, and transfers the wafer holder 68 from the Y-axis turntable 42 to the arm 34 by lifting the arm by a predetermined amount.

Next, the controller moves the wafer holder 68 from the position indicated by the imaginary line 68′ to a position inside the holder container 106. Specifically, according to the information stored in the memory of whether or not individual shelves hold a wafer holder 68, the controller transports the wafer holder 68 to a specified height where the wafer holder 68 is to be stored, using the arm 34 of the robot 32, has the robot 32 stretch and insert the arm 34 into a little above an empty shelf of the holder container 106, and has the wafer holder 68 delivered to the shelf by lowering the arm 34 of the robot 32. Then the robot folds and moves the arm 34 out of the holder container 106.

Meanwhile, the wafer holder 68 is loaded onto the wafer stage WST in the following manner.

First the controller drives the robot 32 up or down depending on the height of the wafer holder to be accessed according to the information of whether or not individual shelves hold a wafer holder 68, which information is stored in the memory. That is, the controller moves the robot 32 to such a height that the robot 32 can insert the arm 34 between the wafer holder to be accessed and an obstacle under it (another wafer holder or the bottom of the controller 106).

Next, the controller inserts the arm 34 of the robot 32 under the wafer holder to be accessed by rotating, and stretching and folding the arm 34 via the drive portion 36, lifts the arm 34 by a small amount to receive the wafer holder 68, and takes the wafer holder 68 out of the holder container 106 by folding the arm 34 of the robot 32. Next, the controller has the robot 32 transport the wafer holder 68 to the position indicated by the imaginary line 68′ by rotating, stretching and folding, and lowering the arm 34. Meanwhile, the Y-axis turntable 42 moves to the position indicated by the imaginary line 42′.

Next, the controller has the wafer holder 68 transferred from the arm 34 of the robot 32 to the Y-axis turntable 42 by lowering the arm 34 of the robot 32 (or by lifting the Y-axis turntable 42).

Next, the controller moves the slider 40 and Y-axis turntable 42 as one piece in the +Y direction to transport the wafer holder 68 to the position indicated by the imaginary line 68″.

Next, the controller moves the unload-Y-axis arm 52 standing by in the position indicated by a solid line in FIG. 4 to near the position indicated by the imaginary line W3, and has the Y-axis turntable 42 pass the wafer holder 68 to the unload-Y-axis arm 52 by, e.g., lifting the unload-Y-axis arm 52 (or lowering the Y-axis turntable 42).

After the completion of the delivery of the wafer holder 68 to the unload-Y-axis arm 52, the controller moves the unload-Y-axis arm 52 from the position indicated by the imaginary line W3 in FIG. 4 to the loading position.

After the unload-Y-axis arm 52 has moved to the loading position, the controller has the wafer holder 68 transferred from the unload-Y-axis arm 52 to the delivery mechanism (not shown) on the wafer stage WST standing by in the loading position by lowering the unload-Y-axis arm 52.

Then the stage controller lowers the delivery mechanism for the wafer holder 68 to be loaded onto the wafer stage WST. It is noted that the wafer holder 68 is fixed by, for example, vacuum chuck or electrostatic chuck on the wafer stage WST.

In this manner, wafer holders are replaced at predetermined intervals.

As described above, according to this embodiment, under the control of the controller (not shown) the open-close mechanism 112 opens and closes the door 108 in a manner that the inside of the holder container 106 is isolated from the outside. And when the open-close mechanism 112 opens the door 108, the wafer loader system 100 sequentially performs transporting (unloading) the wafer holder 68 to the inside of the holder container 106 and transporting (loading) another wafer holder 68 in the holder container 106 onto the wafer stage WST. That is, according to this embodiment the wafer holder can be replaced in a short time in a manner that the inside of the apparatus is isolated from the outside. Therefore, the cleanliness of such wafer holders can be maintained all the time, and the down time of the apparatus can be shortened, thereby improving the yield and thus the productivity of devices such as semiconductor devices.

In addition, because in this embodiment the wafer loader system 100 that unloads a wafer from the wafer stage WST and loads a wafer onto the wafer stage WST can also serve as the wafer holder transport system, a different transport system only for wafer holders is not needed, thus preventing the increase of the cost. It is remarked that the different transport system only for wafer holders can be provided.

It is noted that although this embodiment describes the case where transporting a wafer holder 68 on the wafer stage WST into the holder container 106 (unloading) and transporting another wafer holder 68 in the holder container 106 onto the wafer stage WST (loading) are sequentially performed, this invention is not limited to that. Transporting a substrate holder on the substrate stage into the holder container and transporting another substrate holder in the holder container onto the substrate stage may be performed at least partially in parallel, in a transport system for substrate holders. In this case, although the transport system for substrate holders needs two paths, one for loading and the other for unloading, the time for replacing a holder can be shortened because of parallel operations.

Moreover, although the above embodiment describes the case where an open-close-type container having the same structure as a so-called FOUP that can contain a plurality of wafer holders is used as the holder container, not being limited to that, the holder container may be constructed so as to contain only one substrate holder.

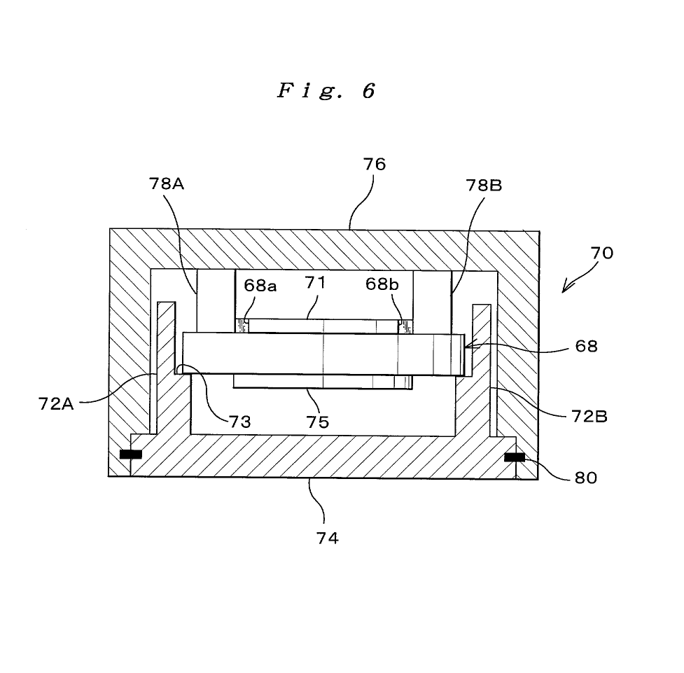

FIG. 6 shows an example of such holder container. This holder container 70 is a container of a SMIF type, the SMIF standing for standard mechanical interface. The holder container 70 comprises a container main body 74 having a pair of supporting members 72A, 72B that support part of the periphery of the opposite face of the wafer holder 68 to a face 71 to contact a wafer and a cover 76 that is detachable from the container main body 74 and that serves as a lid member for isolating the inside from the outside, the part of the periphery being different from other part attaching to the wafer stage WST by chucking. The supporting members 72A, 72B protrude from the upper face of the container main body 74, extend perpendicular to the drawing of FIG. 6 and opposite to each other, and have ‘L’-shaped cross-sections. The sides, inward to the container main body 74, of the supporting members 72A, 72B each have a step 73 formed thereon, the upper face of which supports part of the periphery of the wafer holder 68 from under. Furthermore, there are gaps having a predetermined width between the outward side faces of the supporting members 72A, 72B and the cover 76 as shown in FIG. 6, which gaps are for preventing friction between the supporting members 72A, 72B and the cover 76 and thus limiting the creation of dust as much as possible during the operation of opening the container described later.

The cover 76 has an opening in a whole side that fits on the container main body 74 from above, has a step around the opening and has a pair of holding members 78A, 78B protruding from the inner bottom face thereof, which are made of elastic material such as rubber. When the cover 76 is fitted on the container main body 74, the tips of the pair of supporting members 72A, 72B are pressed against parts of the upper face of the wafer holder 68, which parts are adjacent to the notches 68a, 68b respectively with predetermined pressure as shown in FIG. 6. Furthermore, there is a lock mechanism 80 provided between the container main body 74 and the cover 76, and the lock mechanism 80 is unfastened by an open-close mechanism (not shown) in a manner described later.

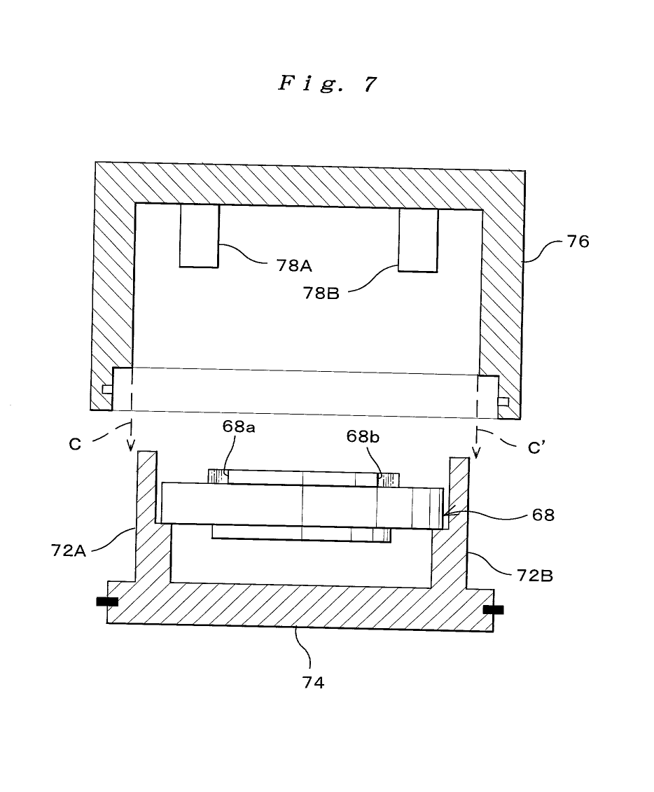

As shown in FIG. 7, the cover 76 is fitted from above, as indicated by arrows C, C′, on the wafer holder 68 of which part of the periphery is supported by the pair of supporting members 72A, 72B arranged on the container main body 74. By this, the step of the cover 76 comes to engage with the periphery of the container main body 74, and therefore the cover 76 can be attached to the container main body 74 at a touch. When the cover is attached, as shown in FIG. 6, the holding members 78A, 78B arranged on the cover 76 hold the wafer holder with contacting other part thereof than the face 71 to contact a wafer. And by fastening the lock mechanism 80, the cover 76 is fixed onto the container main body 74.

That is, the holder container 70 contains the wafer holder 68, which container is airtight, and the wafer holder 68 is clamped by the supporting members 72A, 72B and the holding members 78A, 78B. Therefore, by transporting the wafer holder 68 contained in the holder container 70, the wafer holder 68 can be transported in a sealed manner and with preventing the wafer holder 68 from being damaged during the transport. This means ensures the preventing of the face for contacting a wafer and the opposite face, for contacting the wafer stage WST, of the wafer holder 68 from being damaged. Because the holding members 78A, 78B are made of elastic material such as rubber, the wafer holder 68 is held by adequate force because of the elasticity of elastic material, and vibration, etc., during the transport can be prevented from causing friction between the wafer holder 68 and the holding members 78A, 78B and thus scratches.

It is noted that the container main body 74 and the cover 76 forming the holder container 70 are preferably made of antistatic material and may be made of antistatic and transparent material.

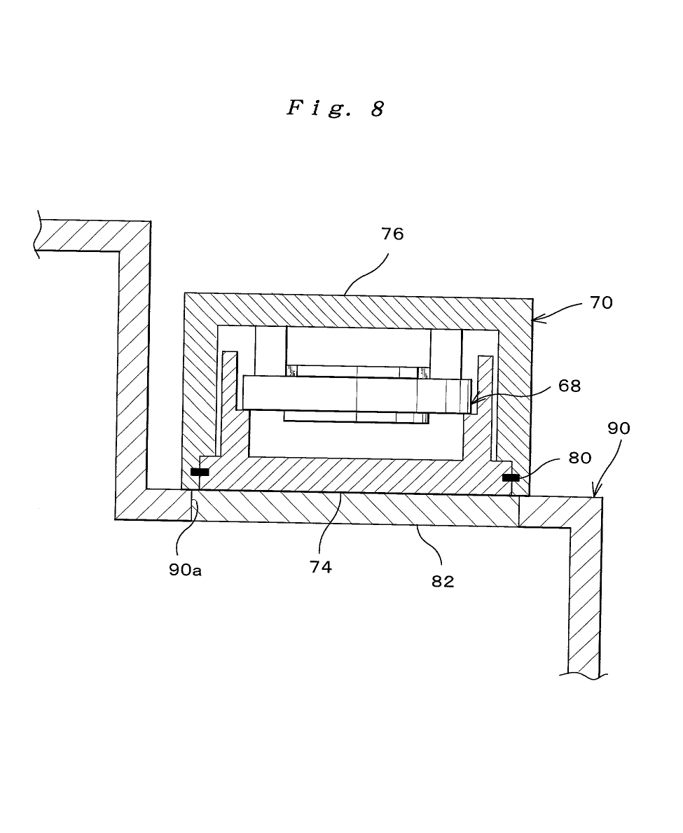

The holder container 70 is mounted on a container-mount 90 as illustrated by FIG. 8. The container-mount 90 is the type of container-mount that the holder container 70 is mounted from above, and, for example, a protrusion formed on part of the first chamber 12 housing the wafer loader system may be used as the container-mount 90. And holder containers are transported to the container-mount 90 using a vehicle of the type to run on the floor such as PGV (Personnel Guided Vehicle) and AGV (Automatic Guided Vehicle) or a vehicle of the type to run along the ceiling such as OHT.

An opening 90a is made in part of the container-mount 90, which opening is slightly larger than the container main body 74 in size. The opening 90a is usually closed by an open-close member 82 forming part of an open-close mechanism (not shown). The open-close member 82 comprises a mechanism (not shown; referred to as an “attach-and-unlock mechanism” for the sake of convenience) that attaches to the container main body 74 by vacuum chucking or mechanical connection and that unfastens the lock mechanism 80 of the container main body 74.

The open-close mechanism unfastens the lock mechanism 80 using the attach-and-unlock mechanism of the open-close member 82, and after the open-close member 82 has attached to the container main body 74, can separate the container main body 74 holding the wafer holder 68 from the cover 76 by lowering the open-close member 82 by a predetermined amount in a manner that the inside of the apparatus is isolated from the outside. In other words, the open-close mechanism can open the cover 76 of the holder container 70 while maintaining the isolation between the inside and outside of the apparatus.

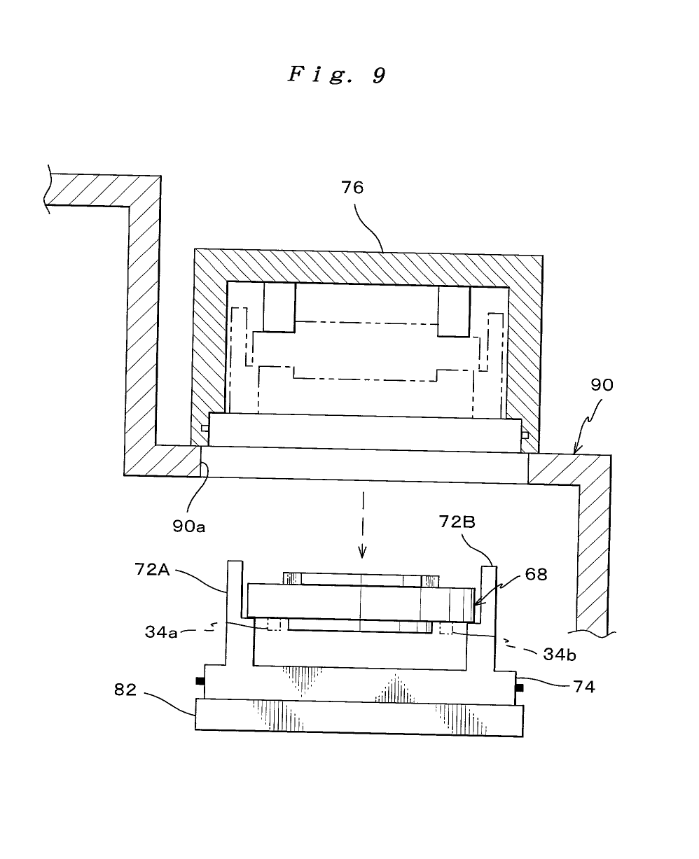

After the container main body 74 is separated from the cover 76, the tips 34a, 34b of the arm 34 of the robot 32 are inserted as shown in FIG. 9, and by lifting the arm by a predetermined amount, the wafer holder 68 is carried out of the container main body 74, the robot 32 forming a part of the wafer loader system. In this case, because the supporting members 72A, 72B support the wafer holder 68 in such positions that the arm 34 does not interfere with the container main body 74, the wafer holder 68 is smoothly carried out of the container main body 74.

In addition, although the holder container 70 can contain only one wafer holder 68, by carrying a dirty wafer holder 68 into the container main body 74 from the wafer stage after carrying the clean wafer holder 68 out of the container main body 74, a wafer holder 68 on the wafer stage can be replaced.

In this manner, also in the case of employing the holder container 70 a wafer holder can be replaced while the inside of the apparatus is isolated from the outside in the same way as in the above embodiment. Therefore, the cleanliness of such wafer holders can be maintained all the time, and the down time of the apparatus can be shortened, thereby improving the yield and thus the productivity of devices such as semiconductor devices.

It is noted that in the above embodiment the arrangement and structure of the first and second chambers, the reticle loader system, the wafer stage system, and the wafer loader system present an example, and that this invention is not limited to that. For example, instead of arranging most of the wafer loader system 100 in the first chamber, the whole or most of the wafer loader system 100 may be arranged in the second chamber 14. In this case, below the second portion 14B, housing the reticle loader system, in the second chamber 14 a sub-chamber can be disposed for housing the wafer loader system 100. If the whole of the wafer loader system 100 is disposed in the second chamber 14, the first chamber may not be needed or may have only an interface portion with C/D 200.

Furthermore, part of the wafer loader system 100 and a transport system only for holders may form a holder transport system. For example, a mechanism (robot arm or the like) for transporting a wafer holder between the position W5 indicated by an imaginary line in FIG. 4 and the holder container may be provided, which mechanism is different from the wafer loader system. Moreover, the holder container and the container-mount may be disposed in another place than the first chamber 12. The point is that the holder container and the container-mount need to be disposed in a space (the second chamber 14, C/D 200, etc.) where desirable environment conditions are maintained. When the holder container and the container-mount are disposed outside the second chamber 14, a holder transport system is preferably arranged inside the second chamber 14 regardless of whether or not it uses at least part of the wafer loader system 100.

Although, in the above embodiment, the holder container and the container-mount are disposed outside the space where desirable environment conditions are maintained, a means may be adopted in which after the holder container is carried into a sub-space of the space and the gas inside the sub-space is replaced with clean gas, the sub-space is communicated to the rest of the space. Moreover, although, in this embodiment, openings for wafers or wafer holders passing through are made in division walls of the first chamber 12, the second chamber 14, and C/D 200, a high-speed shutter may be provided for each of the openings so that the shutter opens the opening only when a wafer or a wafer holder passes through it.

In addition, in the above embodiment the atmospheres inside the holder container and the space are preferably the same. In other words, it is preferable to fill the inside of the container with clean gas so as to set the cleanliness level thereof to be not lower than that of the space (meaning setting the concentration level of impurities to be not higher than that of the space). Additionally, applying this invention to an exposure apparatus comprising two stages produces the same effect as the above. Furthermore, this invention can be applied to the case where a reticle holder that attaches to the surface opposite to the pattern face of a reflection-type reticle by, e.g., vacuum chucking is used and replacement thereof is performed.

In the above embodiment, the exposure apparatus 10 is connected in-line with the C/D 200. However, this invention can be applied to an exposure apparatus that is not connected in-line with the C/D. Moreover, this invention can be applied to not only exposure apparatuses but also manufacturing units (including inspection units) which are used in a device-manufacturing process such as a lithography process and the inside environmental conditions of which need to be kept good.

In addition, in the above embodiment a wafer holder 68 is removed from the wafer stage WST, and then another wafer holder is mounted onto the wafer stage WST. However, a wafer holder 68 removed from the wafer stage WST may be cleaned and then mounted onto the wafer stage WST again.

Like the wafer holder, a reference illuminance meter for providing reference for exposure amount matching between a plurality of exposure apparatuses in the same device-manufacturing line needs to be loaded onto and unloaded from the wafer stage WST. In the prior art, an operator opens the door of a chamber (the chamber 14 in the above embodiment) housing an exposure-apparatus main body and manually loads and unloads the reference illuminance meter onto and from the wafer stage WST as in the cleaning of the wafer stage WST. However, because the loading and unloading of a reference illuminance meter decreases the cleanliness inside the chamber, it is preferable to automate the loading and unloading of a reference illuminance meter from the viewpoint of maintaining the cleanliness. For example, a circular plate, which has the same shape and size as the wafer holder 68 and in which a reference illuminance meter is embedded, may be employed as a dummy holder, and after replacing the wafer holder 68 on the wafer stage WST with the dummy holder using the wafer loader system (or the wafer holder transport system), the control system may detect exposure illumination light, using the reference illuminance meter, and calibrate an integrator sensor, which provides reference for the control of exposure amount in the exposure apparatus. In this case, for example, a wireless type (infrared type), which is used in the well-known television remote-controller, may be employed as a means for transmitting detection results of exposure illumination light by the reference illuminance meter to the control system. Specifically, a micro miniature power, an infrared LED, and a circuit device (IC) that converts a photoelectric-transfer signal outputted from the reference illuminance meter into a signal to drive the infrared LED and that has an encoder, a driver, etc. are embedded in the dummy holder with the reference illuminance meter, and a light receiving portion (having a pin photo-diode and decoder) corresponding to the infrared LED is disposed in a predetermined position of the column of the exposure apparatus. Needless to say, it is possible to use a reference illuminance meter of the wire type that employs wires (cords) as in the prior art. In this case, chemical process such as Teflon coating needs to be performed on the cords so as to prevent gas from emitting from the cords and affecting the exposure apparatus.

It is noted that although in the above embodiment a clean space into which the wafer holder, or the dummy holder, as a substrate holder (or holder) is carried and in which environment conditions are maintained is a chamber, this invention is not limited to that. For example, in an exposure apparatus that employs vacuum ultraviolet light such as F₂ laser as the exposure light source, a purge using inert gas such as nitrogen or helium is usually maintained through transport paths for wafers and reticles as well as the optical path of the exposure light in order to keep environment conditions and cleanliness, and this invention can also be applied to the transport of an object to and from such paths (spaces). That is, in this invention, clean spaces where desirable environment conditions are maintained include the transport paths as well as the chambers. For example, outside the sub-chamber of the second chamber 14 which houses the wafer stage WST and through which a purge with inert gas is maintained, a holder container may be disposed which the holder transport system in the sub-chamber transports wafer holders to and from. Alternatively, a reserve room, in which at least part of the holder transport system is arranged, may be connected to the sub-chamber, and inside or outside the reserve room a holder container may be disposed. Alternatively, inside or outside a reserve room in which at least part of the wafer loader system is arranged and which is connected to the sub-chamber, a holder container may be disposed, and the wafer loader system may also be used as a holder transport system or a holder transport system different from the wafer loader system may be arranged in the reserve room. In this case, the reserve room may consist of a plurality of reserve rooms that are connected with each other and each of which houses part of the transport path, and any of the reserve rooms has the holder container. The holder container is preferably filled with inert gas. In other words, it is preferable that the atmosphere inside the container is substantially the same as that of the spaces (the chambers, the reserve rooms, etc.). Here, the concentration level of impurities (water, moisture, organic substances, etc.) is preferably set to be not higher than that of the spaces, which impurities attenuate the exposure light and which degrade optical characteristics (transmittance, illuminance uniformity, aberration) of the illumination optical system and projection optical system. Moreover, inert gas inside the container may be of a different kind from that of the spaces, or may be a mixture of plural kinds of inert gases. Furthermore, when the concentrations of impurities inside the sub-chamber and a reserve room connected thereto are different, the concentration of impurities inside the container may be set to be close to that of the space in which the container is disposed.

It is noted that although in this embodiment the exposure-apparatus main body 120 performs scan exposure of the step-and-scan method, this invention is not limited to it. The exposure-apparatus main body may be one that performs stationary exposure of a step-and-repeat method. Furthermore, this invention can also be applied to a projection exposure apparatus of a step-and-stitch method, a mirror-projection aligner, an exposure apparatus of a proximity method, and a photo-repeater, and, furthermore, to exposure apparatuses employing a charged-particle beam such as an electron beam or ion beam, or an X-ray (such as soft X-ray emitted from a laser-plasma light source or SOR, e.g., EUV (Extreme Ultraviolet) light having a wavelength of 13.4 nm or 11.5 nm) as exposure illumination light. Incidentally, the main body of an exposure apparatus employing a charged-particle beam or an X-ray is housed in a vacuum chamber.

### A Device-manufacturing Method

Next, an embodiment of the method of manufacturing devices using a lithography system and exposure apparatus thereof according to the above embodiments will be described.

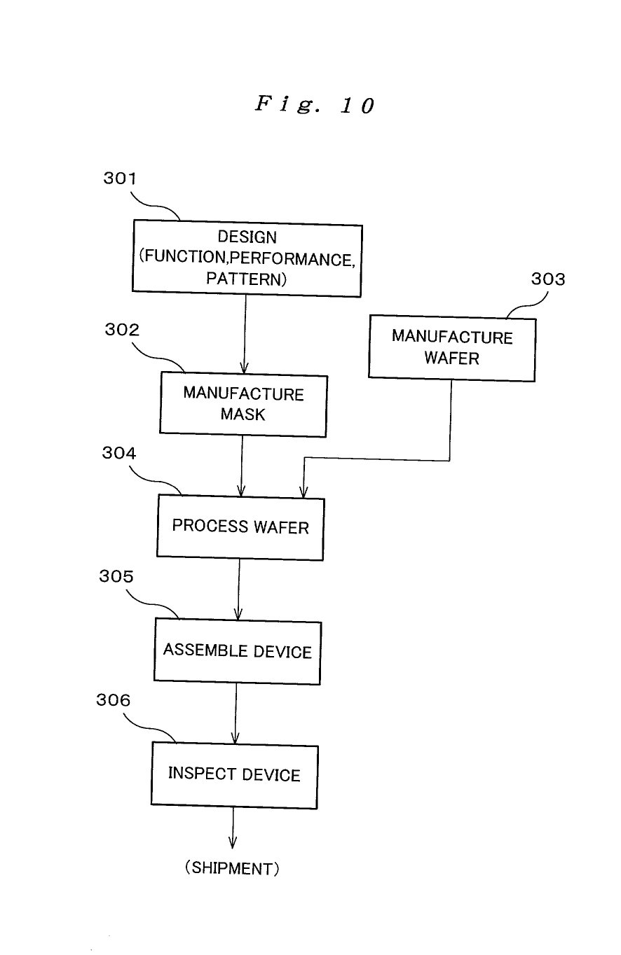

FIG. 10 is a flow chart for the manufacture of devices (semiconductor chips such as IC or LSI, liquid crystal panels, CCD's, thin magnetic heads, micro machines, or the like) in this embodiment. As shown in FIG. 10, in step 301 (design step), function/performance design for the devices (e.g., circuit design for semiconductor devices) is performed and pattern design is performed to implement the function. In step 302 (mask manufacturing step), masks on which a different sub-pattern of the designed circuit is formed are produced. In step 303 (wafer manufacturing step), wafers are manufactured by using silicon material or the like.

In step 304 (wafer processing step), actual circuits and the like are formed on the wafers by lithography or the like using the masks and the wafers prepared in steps 301 through 303, as will be described later. In step 305 (device assembly step), the devices are assembled from the wafers processed in step 304. Step 305 includes processes such as dicing, bonding, and packaging (chip encapsulation), as needed.

Finally, in step 306 (inspection step), a test on the operation of each of the devices, durability test, and the like are performed. After these steps, the process ends and the devices are shipped out.

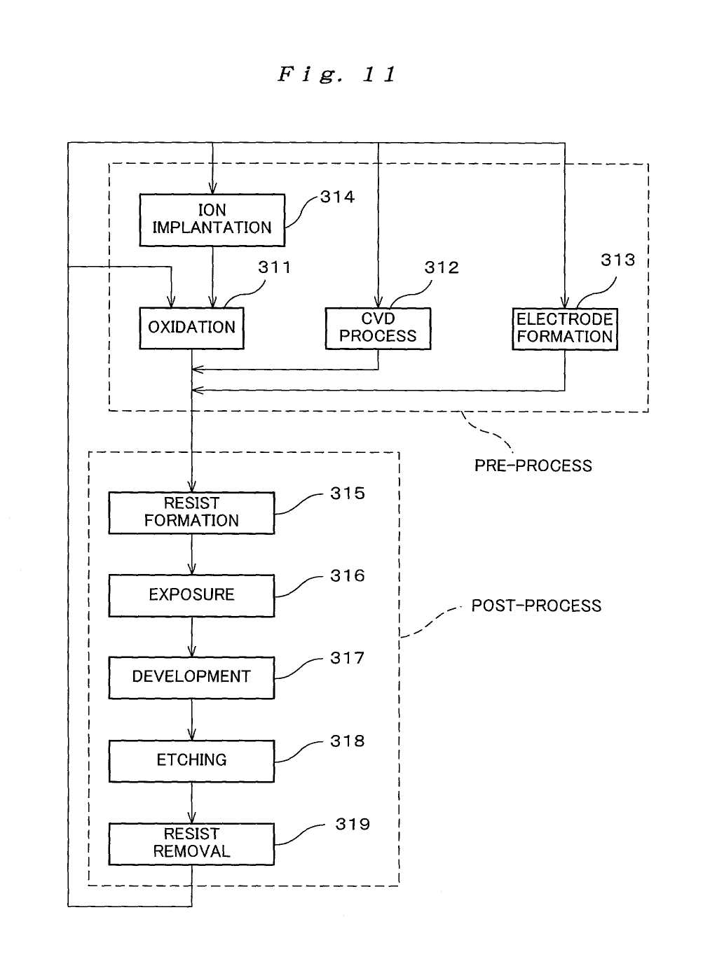

FIG. 11 is a flow chart showing a detailed example of step 304 described above in manufacturing semiconductor devices. Referring to FIG. 11, in step 311 (oxidation step), the surface of a wafer is oxidized. In step 312 (CVD step), an insulating film is formed on the wafer surface. In step 313 (electrode formation step), electrodes are formed on the wafer by vapor deposition. In step 314 (ion implantation step), ions are implanted into the wafer. Steps 311 through 314 described above constitute a pre-process for each step in the wafer process and are selectively executed in accordance with the processing required in each step.

When the above pre-process is completed in each step in the wafer process, a post-process is executed as follows. In this post-process, first of all, in step 315 (resist formation step), the wafer is coated with a photosensitive material (resist). In step 316, the above exposure apparatus transfers a sub-pattern of the circuit on a mask onto the wafer according to the above method. In step 317 (development step), the exposed wafer is developed. In step 318 (etching step), an exposing member on portions other than portions on which the resist is left is removed by etching. In step 319 (resist removing step), the unnecessary resist after the etching is removed.

By repeatedly performing these pre-process and post-process, a multiple-layer circuit pattern is formed on each shot-area of the wafer.

According to the device-manufacturing method of this embodiment described above, in the exposure step (step 316), the lithography system 1 and exposure apparatus 10 are used, and therefore it is possible to manufacture devices with keeping the wafer holder on the wafer stage WST clean and improve the yield of the devices, and because the down time of the apparatus for replacing the wafer holder is short, highly integrated devices can be manufactured with good productivity.

Although the embodiments according to the present invention are preferred embodiments, those skilled in the art of lithography systems can readily think of numerous additions, modifications and substitutions to the above embodiments, without departing from the scope and spirit of this invention. It is contemplated that any such additions, modifications and substitutions will fall within the scope of the present invention, which is defined by the claims appended hereto.

What is claimed is:

1. An exposure apparatus that exposes a substrate held by a substrate holder on a substrate stage, said exposure apparatus comprising:
a container-mount on which a holder container is mounted which contains a substrate holder and which has a lid member that can be opened and closed;
an open-close mechanism that opens and closes said lid member in a manner that the inside of said holder container mounted on said container-mount is isolated from the outside; and
a holder transport system that transports said substrate holder between said holder container and said substrate stage when said open-close mechanism has opened said lid member.

2. The exposure apparatus according to claim 1, wherein said holder container can contain a plurality of substrate holders at the same time.

3. The exposure apparatus according to claim 2, wherein said holder transport system performs transport of one of said substrate holders into said holder container and transport of another of said substrate holders from said holder container in parallel.

4. The exposure apparatus according to claim 2, wherein said holder transport system performs sequentially transport of one of said substrate holders from said substrate stage into said holder container and transport of another of said substrate holders from said holder container onto said substrate stage.

5. The exposure apparatus according to claim 1, wherein said holder transport system also serves as at least part of a transport system for said substrate.

6. The exposure apparatus according to claim 1, wherein said holder container comprises: a container main body on which supporting members are provided which support part of the periphery of a face opposite to a face, of said substrate holder, to contact a substrate; a lid member that is detachable from said container main body and isolates the inside space from the outside; holding members that are provided on said lid member and each hold part of said face, of said substrate holder, to contact said substrate, which part is different from part to contact the substrate; and a lock mechanism that fixes said lid member to said container main body and can be released, and
wherein said holder transport system includes a transport arm that transports said substrate holder into and from said holder container when said lid member is opened.

7. The exposure apparatus according to claim 1, wherein said holder transport system performs said transporting of a substrate holder each time exposure of a predetermined number of substrates is completed.

8. The exposure apparatus according to claim 1, wherein after having unloaded the substrate holder from said substrate stage, said holder transport system loads said substrate holder, which has been cleaned after the unloading, onto said substrate stage again.

9. A device-manufacturing method including a lithography process, wherein in said lithography process, exposure is performed using the exposure apparatus according to claim 1.

10. An exposure apparatus that transfers a pattern onto a substrate by illuminating a mask having said pattern formed thereon with illumination light, said exposure apparatus comprising:
a stage that has a set-position from which a detection unit capable of detecting said illumination light is detachable and that is movable holding said substrate; and
a transport system that transports said detection unit to said set-position of said stage.

11. The exposure apparatus according to claim 10, wherein said detection unit detachable from said set-position on said stage comprises a sending portion that sends a radio signal according to illumination light detected; and a power supply portion that supplies power to said sending portion for driving it.

12. The exposure apparatus according to claim 11, further comprising:
a substrate holder that has a predetermined shape and is provided in a specific position on said stage and holds said substrate;
wherein said detection unit has the same shape as said substrate holder.

13. The exposure apparatus according to claim 12, wherein said transport system transports said detection unit to said set-position on said stage and said substrate holder holding a substrate to said specific position on said stage.

14. The exposure apparatus according to claim 11, further comprising:
a sensor that detects said illumination light; and
a control system that controls said illumination light according to detection results of said sensor;
wherein said sensor is adjusted using said detection unit, which is provided in said set-position on said stage and which is detachable.

15. A transport system that transports a holder holding an object in a clean space where environmental conditions are maintained, said transport system comprising:
a container that has an inside space where one or more holders can be contained and a lid member that isolates said inside space from the outside;
an open-close mechanism that opens and closes said lid member of said container; and
a holder transport system that transports a holder between said container and said clean space when said open-close mechanism has opened said lid member.

16. The transport system according to claim 15, wherein said holder transport system transports a holder out of said clean space, and transports said holder, which has been cleaned after the transporting-out, into said clean space.

17. The transport system according to claim 15, wherein said holder transport system performs sequentially transport of one of said holders from said clean space into the inside of said container and transport of another of said holders from the inside of said container into said clean space.

18. The transport system according to claim 15, wherein said holder transport system comprises a loading unit that transports a holder from the inside of said container into said clean space; and a unloading unit that transports a holder from said clean space into the inside of said container and that is different from said loading unit, and
wherein loading of a holder by said loading unit and unloading of another holder by said unloading unit are performed partially in parallel.

19. The transport system according to claim 15, further comprising:
a container transport system that transports said container containing at least one holder.

20. The transport system according to claim 19, wherein said container transport system includes any one of a floor-moving-type vehicle and a ceiling-moving-type vehicle.

21. The transport system according to claim 15, wherein the atmosphere of the inside of said container is substantially the same as that of said clean space.

22. The transport system according to claim 21, wherein after having carried a holder into said clean space, said holder transport system transports an object that is to be held by said holder to said clean space.

23. An exposure system comprising an exposure apparatus that transfers a pattern formed on a mask onto a photo-sensitive substrate, said exposure system wherein
a substrate holder to hold said photo-sensitive substrate is transported to a predetermined position of said exposure apparatus by said transport system of claim 15.

24. An exposure system comprising an exposure apparatus that transfers a pattern formed on a mask onto a photo-sensitive substrate, said exposure system wherein
a holder in which a reference illuminance meter is embedded is transported to a predetermined position of said exposure apparatus by said transport system of claim 15.

25. The exposure system according to claim 24, wherein said reference illuminance meter has a radio-type transmitter that transmits detection results of exposure illumination light to a control system.

26. A holder container that contains a substrate holder that can hold a substrate, said holder container comprising:
at least one supporting member that supports at least one substrate holder; and
a lid member that isolates the inside space, where said at least one supporting member is provided, from the outside;
wherein said at least one substrate holder is contained in said inside space isolated from the outside by said lid member.

27. The holder container according to claim 26, wherein a plurality of shelves that can hold a plurality of substrate holders are provided for said at least one supporting member.

28. The holder container according to claim 26, wherein said at least one supporting member supports each said at least one substrate holder by touching other part of said substrate holder than part that contacts said substrate when said substrate holder holds said substrate.

29. The holder container according to claim 26, wherein said at least one supporting member supports each said at least one substrate holder in part thereof so as not to interfere with an unloading arm that unloads said at least one substrate holder from said inside space.

30. The holder container according to claim 26, wherein a gap is provided between said at least one supporting member and said lid member.

31. The holder container according to claim 26, wherein said at least one supporting member and said lid member are made of anti-static material.

32. The holder container according to claim 31, further comprising:
at least one holding member that is provided on said lid member and holds part of said face, of said substrate holder, to contact said substrate, and
wherein said at least one holding member is at least partially made of elastic material.

33. The holder container according to claim 26, wherein said at least one supporting member is provided in the main body of said holder container, which can engage with said lid member, said holder container further comprising:
a lock mechanism that fixes said lid member to said container main body and can be released.

34. A device-manufacturing unit that has a holder, to hold an object, arranged in a space of which cleanliness is higher than that of the outside, said device-manufacturing unit comprising:
an open-close mechanism that communicates the inside of a container containing said holder in a sealed manner to said space while isolating the inside of said container from said outside; and
a transport system that transports said holder between said container and said space.

35. The device-manufacturing unit according to claim 34, wherein the concentration of impurities inside said container is set at a level not higher than that of said space.

36. The device-manufacturing unit according to claim 34, wherein the atmosphere inside said container is set to be substantially the same as that of said space.

37. The device-manufacturing unit according to claim 36, wherein said container is filled with gas having substantially the same characteristics as that of said space.

38. The device-manufacturing unit according to claim 34, wherein said holder holds a sensitive object, and wherein an exposure main body that exposes said sensitive object to an energy beam is arranged in said space.

39. The device-manufacturing unit according to claim 38, wherein chemically clean gas having high transmittance to said energy beam is supplied to said space.

40. An adjustment method with which to adjust a device-manufacturing unit that has a holder, to hold an object, arranged in a space thereof having a higher cleanliness than that of the outside of said device-manufacturing unit, said adjustment method wherein the inside of a container to contain a holder in a sealed manner is communicated to said space in a manner that the inside of said container is isolated from said outside, and wherein a holder is transported from said space into said container, and a clean holder is transported into said space.

41. A detection unit that can be used in an exposure apparatus that transfers a pattern formed on a mask onto a substrate by illuminating said mask with illumination light, said detection unit comprising:
a detecting portion that can detect illumination light; and
a power supply portion that supplies power to said detecting portion for driving it, and
which is transported by a transport system of said exposure apparatus in order to be set up in a predetermined position inside said exposure apparatus.

42. The detection unit according to claim 41, further comprising:
a sending portion that sends a radio signal according to detection results of said detecting portion.

43. The detection unit according to claim 42, which: has the same shape as a substrate holder in a predetermined shape, which holds said substrate used in said exposure apparatus.

44. The detection unit according to claim 41, which: has such a shape that a transport unit, which transports a substrate holder holding said substrate, can transport said detection unit, said substrate being used in said exposure apparatus.

45. The detection unit according to claim 41, which: detects illuminance of said illumination light.
